(19) United States
(12) Patent Application Publication
(10) Pub. No.: US 2024/0222589 A1
(43) Pub. Date: Jul. 4, 2024

(54) LIGHT-EMITTING MODULE, METHOD FOR SORTING THE SAME, AND DISPLAY DEVICE

(71) Applicant: HUBEI SAN’AN OPTOELECTRONICS CO., LTD., Ezhou (CN)

(72) Inventors: Zhenduan LIN, Ezhou (CN); Junpeng SHI, Ezhou (CN); Zhiyang ZENG, Ezhou (CN); Chenke HSU, Ezhou (CN); Changchin YU, Ezhou (CN); Jieling WANG, Ezhou (CN)

(21) Appl. No.: 18/603,731

(22) Filed: Mar. 13, 2024

Related U.S. Application Data
(63) Continuation-in-part of application No. PCT/CN2023/080331, filed on Mar. 8, 2023.

(30) Foreign Application Priority Data
Jun. 18, 2022 (CN) 202210691149.3

(51) Int. Cl. H01L 33/62; H01L 25/075; H01L 33/24; H01L 33/54

(52) U.S. Cl. CPC H01L 33/62; H01L 25/0753; H01L 33/24; H01L 33/54; H01L 2933/005; H01L 2933/0066

(57) ABSTRACT

A light-emitting module includes a plurality of light-emitting elements, a plurality of conductive pads, and a package layer. Each of the light-emitting elements has a light-emitting surface and a back surface opposite to the light-emitting surface. The conducive pads are disposed above the back surfaces of the light-emitting elements. The package layer is disposed around the conducive pads, and has a guiding structure which is formed between two adjacent ones of the conducive pads and which extends in a direction orthogonal to a thickness direction of the package layer so as to extend across the package layer. A display device including the light-emitting module, and a method for sorting the light-emitting modules are also provided.

### CROSS-REFERENCE TO RELATED APPLICATION

This application is a continuation-in-part (CIP) of International Application No. PCT/CN2023/080331, filed on Mar. 8, 2023, which claims priority to Chinese Invention Patent Application No. 202210691149.3, filed on Jun. 18, 2022. The aforesaid applications are incorporated by reference herein in their entirety.

### FIELD

The disclosure relates to a semiconductor device, and more particularly to a light-emitting module, a method for sorting the same. The disclosure also relates to a display device including the light-emitting module.

### BACKGROUND

Small-sized red-green-blue (RGB) light-emitting diodes (LEDs) are growing rapidly in the field of display screens, and their applications are becoming more widespread. Although the small-sized RGB LEDs can bring forth an extremely high pixel density and thus deliver a favorable resolution, the manufacturing process thereof faces great challenges. One of the conventional methods for sorting LEDs may be completed by a sorting machine that sorts the LEDs by using a blue film, and another one of the methods may involve use of the sorting machine by means of vibration. As the size of LED products becomes smaller, sorting by means of vibration is met with difficulties and the efficiency of doing so may be reduced.

Nowadays, another sorting method involves identification of directions of LED packaging products using an imaging equipment, but such LED packaging products must be subjected to good imaging to complete the sorting. If the LED packaging products cannot be properly photographed due to the arrangement caused by discharge direction thereof, an additional alignment work is required to be performed in accordance with the characteristics of the LED packaging products. This method has great limitations in terms of both identification and packaging efficiencies.

Therefore, those skilled in the art strive to develop a technique that can enhance the efficiency in identification of the directions of the LED packaging products.

### SUMMARY

Therefore, an object of the disclosure is to provide a light-emitting module, a display device including the same, and a method for sorting light-emitting modules that can alleviate at least one of the drawbacks of the prior art.

According to a first aspect of the disclosure, a light-emitting module includes a plurality of light-emitting elements, a plurality of conductive pads, and a package layer. The light-emitting elements are spacedly arranged, and each of the light-emitting elements has a light-emitting surface and a back surface opposite to the light-emitting surface. The conductive pads are disposed above the back surfaces of the light-emitting elements. The package layer is disposed around the conductive pads. In addition, the package layer has a guiding structure which is formed between two adjacent ones of the conductive pads and which extends in a direction orthogonal to a thickness direction of the package layer so as to extend across the package layer.

According to a second aspect of the disclosure, a light-emitting module includes a plurality of light-emitting elements that are spacedly arranged. The light-emitting module has a three-dimensional structure which is formed with a guiding structure. The guiding structure extends in a direction orthogonal to a thickness direction of the three-dimensional structure so as to extend across the three-dimensional structure.

According to a third aspect of the disclosure, a method for sorting light-emitting modules includes the steps of:
(a) feeding a plurality of light-emitting modules into a track of a sorting machine, each of the light-emitting modules having a guiding structure, the track of the sorting machine having a sorting structure; and
(b) moving the light-emitting modules along the track of the sorting machine, such that those of the light-emitting modules that have the guiding structures engaging with the sorting structure pass through the track of the sorting machine while those of the light-emitting modules that have the guiding structures not engaging with the sorting structure are blocked and are not allowed to pass through the track of the sorting machine, thereby sorting the light-emitting modules.

According to a fourth aspect of the disclosure, a display device includes a panel and a plurality of light-emitting modules. The panel includes a circuit layer and a device layer which is electrically connected to the circuit layer. The light-emitting modules are disposed on the panel, and each of the light-emitting modules is electrically connected to the device layer via the circuit layer. Each of the light-emitting modules is the light-emitting module of the first aspect.

According to a fifth aspect of the disclosure, a display device includes a panel and a plurality of light-emitting modules. The panel includes a circuit layer and a device layer which is electrically connected to the circuit layer. The light-emitting modules are disposed on the panel, and each of the light-emitting modules is electrically connected to the device layer via the circuit layer. Each of the light-emitting modules is the light-emitting module of the second aspect.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating a first embodiment of a light-emitting module according to the disclosure.

FIG. 2 is a cross-sectional view of the first embodiment taken along line L1-L1 of FIG. 1.

FIG. 3A is a schematic view illustrating a track for sorting the light-emitting module of the first embodiment.

FIG. 3B is a schematic view illustrating the light-emitting module of the first embodiment being sorted through the track of FIG. 3A.

FIG. 3C is a schematic view illustrating another track for sorting the light-emitting module of the first embodiment.

FIG. 3D is a schematic view illustrating the light-emitting module of the first embodiment being sorted after rotating on the track of FIG. 3C.

FIG. 4 is a schematic plan view illustrating the light-emitting module of the first embodiment.

FIG. 5 is a flow chart illustrating a method for manufacturing the light-emitting module of the first embodiment.

FIG. 6A is a schematic plan view illustrating step (2) of the method for manufacturing the light-emitting module of the first embodiment.

FIG. 6B is a cross-sectional view taken along line B-B′ of FIG. 6A.

FIG. 7 is a cross-sectional view illustrating step (3) of the method for manufacturing the light-emitting module of the first embodiment.

FIG. 8A is a schematic plan view illustrating step (4) of the method for manufacturing the light-emitting module of the first embodiment.

FIG. 8B is a cross-sectional view taken along line B-B′ of FIG. 8A.

FIG. 8C is an enlarged view of portion I of FIG. 8A.

FIG. 9A is a schematic plan view illustrating step (5) of the method for manufacturing the light-emitting module of the first embodiment.

FIG. 9B is a cross-sectional view taken along line B-B′ of FIG. 9A.

FIG. 10 is a cross-sectional view illustrating step (6) of the method for manufacturing the light-emitting module of the first embodiment.

FIG. 11 is a cross-sectional view illustrating a variation of the light-emitting module of the first embodiment.

FIG. 12 is a schematic plan view illustrating another variation of the light-emitting module of the first embodiment.

FIG. 13 is a schematic view illustrating a second embodiment of a light-emitting module according to the disclosure.

FIG. 14 is a cross-sectional view taken along line L2-L2 of FIG. 13.

FIG. 15 is a schematic view illustrating the light-emitting module of the second embodiment being engaged with a sorting structure of the track.

FIG. 16 is a schematic view illustrating a third embodiment of a light-emitting module according to the disclosure.

FIG. 17 is a cross-sectional view illustrating an embodiment of a display device according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

### First Embodiment

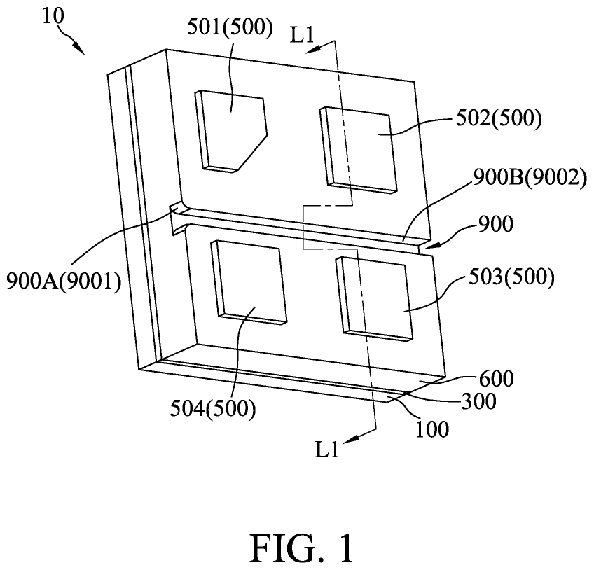

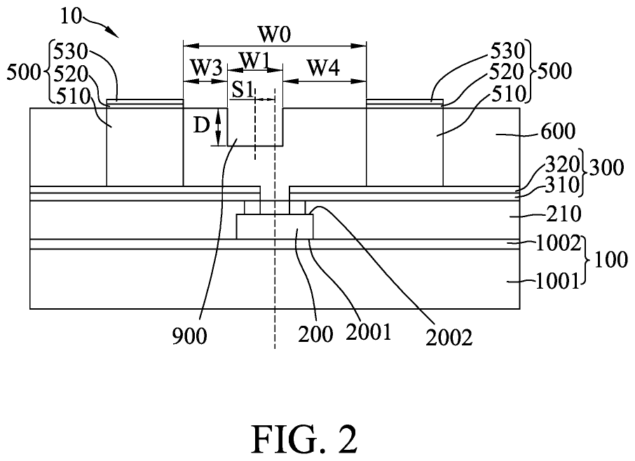

Referring to FIGS. 1 and 2, a first embodiment of a light-emitting module 10 according to the disclosure includes a plurality of light-emitting elements 200 (only one is shown) that are spacedly arranged, a plurality of conductive pads 500, and a package layer 600. Each of the light-emitting elements 200 has a light-emitting surface 2001 and a back surface 2002 opposite to the light-emitting surface 2001. The conductive pads 500 and the package layer 600 are formed and disposed above the back surfaces 2002 of the light-emitting elements 200 opposite to the light-emitting surfaces 2001.

Referring to FIGS. 1 and 2, the light-emitting elements 200 are arranged at intervals, and emit light having different wavelength ranges. The light-emitting module 10 further includes a filling layer 210 and a wiring layer 300. The filling layer 210 is filled in a space among the light-emitting elements 200 so that the light-emitting elements 200 are electrically isolated. The wiring layer 300 is formed above the light-emitting elements 200 and is electrically connected to the light-emitting elements 200. The conductive pads 500 are formed on a side of the wiring layer 300 distant from the light-emitting elements 200 and are electrically connected to the light-emitting elements 200 through the wiring layer 300.

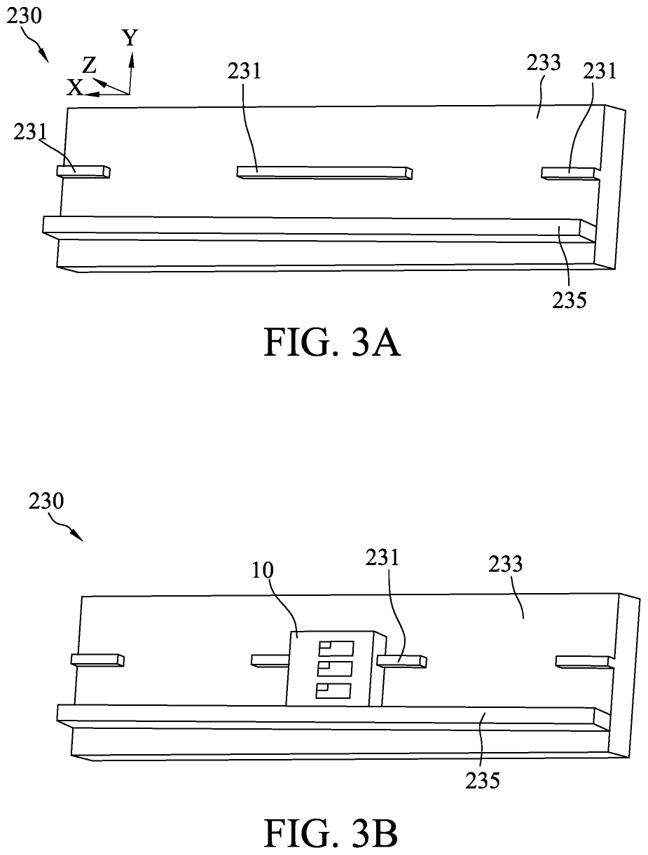

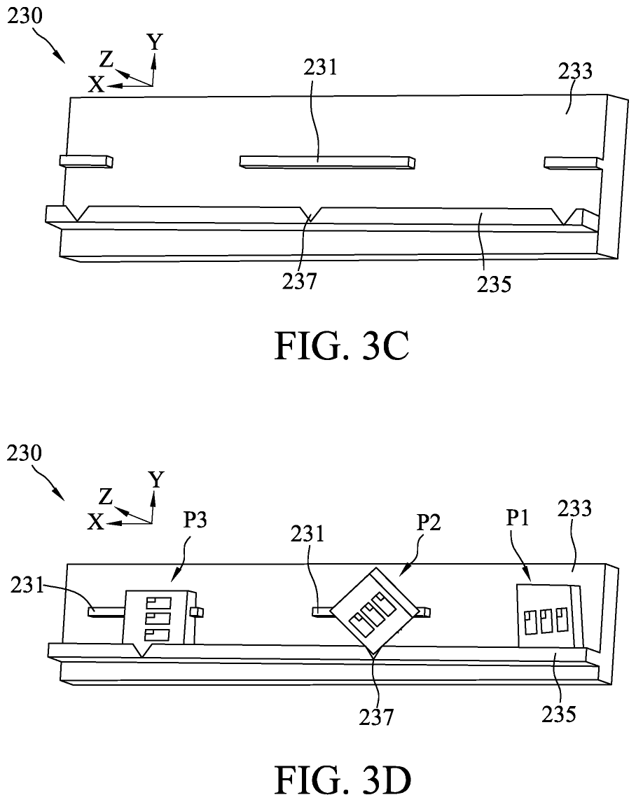

As shown in FIGS. 1 and 2, the package layer 600 is filled and disposed around the conductive pads 500 so that two adjacent ones of the conductive pads 500 are electrically isolated. In certain embodiments, a surface of the package layer 600 distant from the wiring layer 300 is flush with surfaces of conductive layers 510 of the conductive pads 500 distant from the wiring layer 300. In certain embodiments, each of the conductive pads 500 has an exposed surface which is exposed from the package layer 600, and the light-emitting module 10 has a top surface including a surface of the package layer 600 and the exposed surface of each of the conductive pads 500. Moreover, a total surface area of the exposed surfaces of the conductive pads 500 ranges from 20% to 70% of a surface area of the top surface of the light-emitting module 10. The package layer 600 has a guiding structure 900 which is formed between two adjacent ones of the conductive pads 500 and which extends in a direction orthogonal to a thickness direction of the package layer 600 so as to extend across the package layer 600. For example, in some embodiments, the direction along which the guiding structure 900 extends is a length direction of the light-emitting module 10 (i.e., a length direction of the package layer 600), and the guiding structure 900 has two opposite ends having the same width. In still some embodiments, a position of the guiding structure 900 is relative offset with respect to a center line of the light-emitting module 10. That is to say, a center line of the guiding structure 900 is separated from the center line of the light-emitting module 10 by a distance. In certain embodiments, the distance ranges from 10 μm to 60 μm. Such distance enables the light-emitting module 10 to be exclusively fitted to a sorting structure 231 of a track 230 of a sorting machine after being fed into the track 230 (as shown in FIGS. 3A and 3B).

In yet some embodiments, the center line of the guiding structure 900 is aligned with the center line of the light-emitting module 10, in other words, the center line of the guiding structure 900 and the center line of the light-emitting module 10 are arranged to overlap each other. Such configuration of the guiding structure 900 allows the light-emitting module 10 to be initially screened in a direction parallel to a direction along which the guiding structure 900 extends after the light-emitting module 10 enters the track 230 of the sorting machine. The light-emitting module 10 is then subjected to an electrical test, so as to complete a final screening of the light-emitting module 10. Since the center line of the guiding structure 900 and the center line of the light-emitting module 10 overlap each other, i.e., the guiding structure 900 is disposed in the middle of the light-emitting module 10, a distance between the guiding structure 900 and one of two adjacent ones of the conductive pads 500 is equal to a distance between the guiding structure 900 and the other one of the two adjacent ones of the conductive pads 500. Compared with a situation where the center line of the guiding structure 900 is separated from the center line of the light-emitting module 10, a minimum distance (in a situation where the center line of the guiding structure 900 overlaps the center line of the light-emitting module 10) between the guiding structure 900 and one of the two adjacent ones of the conductive pads 500 increases, so that the conductive pads 500 can be prevented from being collided or rubbed after the light-emitting module 10 enters the track 230, thereby ensuring the integrity and electrical performance of the conductive pads 500.

As shown in FIGS. 1 and 2, in this embodiment, the guiding structure 900 is a groove. The groove is formed between two adjacent ones of the conductive pads 500 that are oppositely arranged, and is offset relative to the center line of the light-emitting module 10. That is to say, a center line of the groove (i.e., the center line of the guiding structure 900) is separated from the center line of the light-emitting module 10 by a distance (S1). In certain embodiments, the distance (S1) may range from 10 μm to 60 μm. In certain embodiments, the distance (S1) may range from 20 μm to 40 μm.

In order to ensure the integrity of the package layer 600 without adversely affecting the functionality thereof, the groove (i.e., the guiding structure 900) may have a width (W1) ranging from 10% to 65% of a distance (W0) between the two adjacent ones of the conductive pads 500 (e.g., a distance between inner surfaces of the two adjacent ones of the conductive pads 500 which face each other). In addition, as shown in FIG. 2, the two adjacent ones of the conductive pads 500 are respectively spaced apart from two edges of the groove by distance (W3) and distance (W4). The distance (W3) and the distance (W4) are both greater than 20 μm. In this embodiment, the distance (W3) is smaller than the distance (W4). Moreover, the groove may have a depth (D) which ranges from one-twentieth to one-third of a thickness of the light-emitting module 10 and which may be less than a thickness of the package layer 600. For instance, when the thickness of the light-emitting module 10 is approximately 150 μm, the thickness of the package layer 600 is approximately 30 μm to 60 μm, and the distance (W0) between the inner surfaces of the two adjacent ones of the conductive pads 500 ranges from 100 μm to 120 μm, the width (W1) of the groove may be less than 50 μm, and the depth (D) of the groove may be greater than 10 μm and less than 40 μm. The design of the width (W1) and the depth (D) allows the groove to fit with the sorting structure 231 of the track 230 (as shown in FIG. 3B) so that the light-emitting module 10 will not fall off, and hence the integrity and functionality of the package layer 600 can be ensured.

In some embodiments, the groove includes a straight portion 900B having two inner surfaces 9002 which face each other, and a chamfered portion 900A which is formed at one end of the straight portion 900B and which has two chamfered surfaces 9001 respectively extending from the inner surfaces 9002 of the straight portion 900B. In addition, a chamfer angle of each of the chamfer surfaces 901 with respect to a corresponding one of the inner surfaces 9002 ranges from 15 degrees to 60 degrees. The light-emitting module 10 enters the track 230 with the chamfered portion 900A facing toward an entrance direction so that the groove may easily fit with the sorting structure 231 of the track 230. In still some embodiments, the chamfer angle may range from 30 degrees to 60 degrees. In yet some embodiments, the chamfer angle may range from 30 degrees to 45 degrees. The design of the chamfered portion 900A allows the groove to be easily matched with the sorting structure 231 when the light-emitting module 10 is fed into the track 230. After being fed into the track 230, the light-emitting module 10 can be stably engaged with the sorting structure 231, so as to avoid hard collision therebetween, thereby preventing the light-emitting module 10 from falling off or being damaged.

Referring to FIG. 3A, in an embodiment, the sorting machine may include the track 230 for transporting the light-emitting module 10. In addition, the track 230 of the sorting machine may have the sorting structure 231 disposed thereon. The track 230 may have a carrying surface 233 that carries and keeps the light-emitting module 10 advancing on the track 230, and a protruding wall 235 that extends from the carrying surface 233 in a direction away from the carrying surface 233. The sorting structure 231 is disposed on the carrying surface 233. As shown in FIG. 3A, the sorting structure 231 is a sorting ridge protruding outwardly from the carrying surface 233. In certain embodiments, the sorting ridge may be perpendicular to the carrying surface 233. The sorting structure 231 extends along a first direction on the carrying surface 233, where the first direction is an advancing direction along which the light-emitting module 10 advances on the track 230, i.e., the X direction as shown in FIG. 3A. One or a plurality of the sorting ridge(s) may be disposed on the track 230. When only one of the sorting ridge is provided on the track 230, in such situation, the sorting ridge may have a structure extending across the carrying surface 233. When a plurality of the sorting ridges are provided thereon, the sorting ridges may be disposed at intervals along a straight line in the X direction on the carrying surface 233 of the track 230. In some embodiments, a length of the sorting ridge is greater than a length of the guiding structure 900 of the light-emitting module 10 so that the sorting ridge can be matched with the guiding structure 900 of the light-emitting module 10. The length of the sorting ridge may be greater than or equal to 100 μm, 200 μm, 300 μm, 400 μm, 500 μm, 600 μm, 700 μm, 800 μm, or 1000 μm. In case that when a plurality of the sorting ridges are provided on the carrying surface 233, the sorting ridges may be disposed at intervals by a distance greater than or equal to 100 μm, 200 μm, 300 μm, 400 μm, 500 μm, 600 μm, 700 μm, 800 μm, or 1000 μm.

The lengths of the plurality of the sorting ridges provided on the track 230 may be the same or different, and the distances between two adjacent ones of the sorting ridges disposed along the straight line may be the same or different. When the light-emitting module 10 has a size of 200 μm×200 μm, the length of each of the sorting ridges is greater than 200 μm, such as 220 μm, 300 μm, or 350 μm. When the light-emitting module 10 has a size of 400 μm×400 μm, the length of each of the sorting ridges is greater than 400 μm, such as 450 μm, 500 μm, 600 μm, or 700 μm.

When the light-emitting module 10 has a size of 200 μm×200 μm, the distance between two adjacent ones of the sorting ridges disposed along the straight line may be greater than 200 μm, such as 220 μm, 300 μm, or 350 μm. When the light-emitting module 10 has a size of 400 μm×400 μm, the distance between two adjacent ones of the sorting ridges disposed along the straight line may be greater than 400 μm, such as 450 μm, 500 μm, 600 μm, or 700 μm.

In this embodiment, the groove of the light-emitting module 10 works collaboratively with the sorting ridge(s) of the track 230 disposed on the carrying surface 233, so as to conduct sorting of the light-emitting module 10.

The configuration of the guiding structure 900 allows the light-emitting module 10 to be engaged with the sorting ridge(s) only in a certain direction along the track 230, so that identification and sorting of the light-emitting module 10 can be conducted quickly and efficiently. Referring to FIG. 3B, when the light-emitting module 10 enters the track 230 at a correct direction, i.e., the groove and the sorting ridge(s) properly match with each other, the light-emitting module 10 can be driven by a driving apparatus so as to advance smoothly along the track 230, and may further be transported from the track 230 to a blue film at the end thereof, thus completing sorting and preliminary fixation of the light-emitting module 10. When the light-emitting module 10 enters the track 230 at a wrong direction, i.e., the groove and the sorting ridge(s) cannot match with each other, such as in the case where the groove is perpendicular to the sorting ridge(s) or the groove is located below the sorting ridge(s) though being parallel thereto, the light-emitting module 10 may be pushed away from the carrying surface 233 by the sorting ridge(s) upon passing therethrough. Consequently, under the vibration of the track 230, the light-emitting module 10 may fall off from the carrying surface 0205, and is further subjected to sorting again.

The setting of the distance (S1) between the center line of the groove (i.e., the guiding structure 900) and the center line of the light-emitting module 10 enables the light-emitting module 10 to fit with the sorting ridge(s) on the track 230 during sorting. Moreover, due to such relative offset between the center line of the groove and the center line of the light-emitting module 10, the light-emitting module 10 and the sorting ridge(s) can only match with each other in a certain direction, so that sorting of the light-emitting module 10 can be completed merely by one procedure, which omits the need to use an image sensor or a camera apparatus, and hence enhances the sorting efficiency.

Referring to FIG. 3C, in other embodiments, the track 230 may further include a plurality of tipping structures 237 which are formed at the protruding wall 235 of the track 230. In some embodiments, the tipping structures 237 correspond in position to the sorting ridge(s). In other embodiments, each of the tipping structures 237 is an indentation formed in the protruding wall 235 of the track 230. In still other embodiments, each of the tipping structures 237 is a V-shape indentation. Referring to FIG. 3D, when the groove of the light-emitting module 10 matches well with the sorting ridge(s), the tipping structures 237 do not affect the progress of the light-emitting module 10 on the track 230, which enables sorting to be completed. When the groove of the light-emitting module 10 cannot match with the sorting ridge(s), once reaching the tipping structures 237, the light-emitting module 10 may rotate until the groove of the light-emitting module 10 match with the sorting ridge(s) on the track 230, such that sorting can be completed. To be specific, as shown in FIG. 3D, the light-emitting module 10 enters the track 230 at a first position (P1) where the groove of the light-emitting module 10 is perpendicular to the sorting structure 231 (i.e., the sorting ridge(s)). When the light-emitting module 10 advances to reach a second position (P2), due to blockage by the sorting ridge and engagement with one of the tipping structures 237 and due to the vibration of the track 230, the light-emitting module 10 may rotate 90 degrees relative to the advancing direction (i.e., the X direction) on the track 230. At a third position (P3), the groove of the light-emitting module 10 matches with the sorting ridge and hence the light-emitting module 10 can continuously advance on the track 230 along the advancing direction. After the orientation, the light-emitting module 10 keeps advancing on the track 230 until reaching a blue film, thereby completing sorting.

If the groove of the light-emitting module 10 is parallel to the sorting ridge(s) but located under the sorting ridge(s) when the light-emitting module 10 is at the first position (P1), the light-emitting module 10 may rotate two times in succession under the effect of the tipping structures 237, such that orientation and sorting can be completed.

As described above, the track 230 is provided with the tipping structures 237, and even if the groove of the light-emitting module 10 cannot initially match with the sorting ridge(s), the light-emitting module 10 can be rotated under the effect of the tipping structures 237, so that the groove and the sorting ridge(s) can match with each other eventually, so as to complete sorting. As a result, the sorting efficiency is enhanced.

The present disclosure also provides a method for sorting a plurality of the light-emitting modules 10. The method includes:
(a) feeding the light-emitting modules 10 into the track 230 of the sorting machine, each of the light-emitting modules 10 having the guiding structure 900, the track 230 of the sorting machine having the sorting structure 231; and
(b) moving the light-emitting modules 10 along the track 230 of the sorting machine, such that those of the light-emitting modules 10 that have the guiding structures 900 engaging with the sorting structure 231 pass through the track 230 of the sorting machine while those of the light-emitting modules 10 that have the guiding structures 900 not engaging with the sorting structures 231 are blocked and are not allowed to pass through the track 230 of the sorting machine, thereby sorting the light-emitting modules 10.

In certain embodiments, the track 230 of the sorting machine further has the tipping structure 237 which is configured to be capable of tipping the light-emitting modules 10 to rotate. In addition, in the step (b), those of the light-emitting modules 10 that are blocked by the sorting structure 231 are each rotated by the tipping structure 237 such that the guiding structure 900 thereof becomes engaged with the sorting structure 231.

In certain embodiments, the package layer 600 is an adhesive layer that is capable of absorbing light. The package layer 600 may be made of a material mixed with a black filler component. The material may be, for example, a silicone, an epoxy resin, a polyimide, a low-temperature glass, a polysiloxane, or a polysilazane, and may be transparent or translucent. Examples of the black filler component may include, but are not limited to, carbon black, titanium nitride, iron oxide, ferrous-ferric oxide, and an iron powder.

Since each of the light-emitting element 200 and the wiring layer 300 are relatively thin, the package layer 600 needs to be sufficiently thick to protect the light-emitting element 200 and the wiring layer 300 from damage by an external factor. In certain embodiments, the thickness of the package layer 600 is greater than 20 μm, and each of the conductive pads 500 has a thickness greater than 20 μml. The package layer 600 may be doped with doping particles having a particle size greater than 1 μm, and the doping particles may be, for example, particles of silicon dioxide. By mixing with the doping particles, the mechanical properties of the package layer 600 may be enhanced, thereby further protecting the light-emitting element 200 and the wiring layer 300.

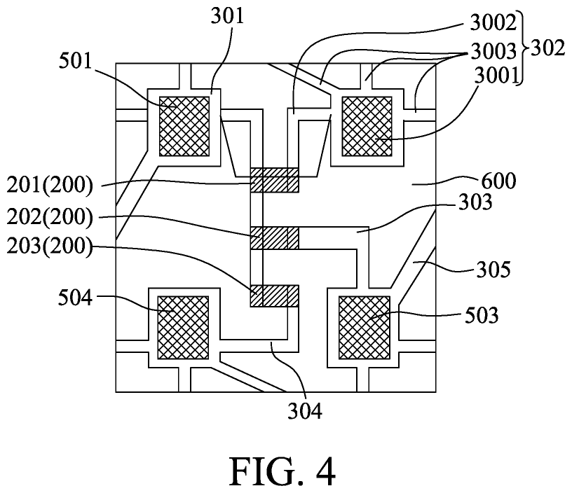

In certain embodiments, the light-emitting element 200 is a micro light-emitting diode, each of which has width and length falling within a range from 2 μm to 5 μm, a range from 5 μm to 10 μm, a range from 10 μm to 20 μm, a range from 20 μm to 50 μm, or a range from 50 μm to 100 μm, and each of which has thickness falling within a range from 2 μm to 15 μm, such as from 5 μm to 10 μm. Referring to FIG. 4, in this embodiment, the light-emitting module 10 includes three light-emitting elements 200, i.e., first light-emitting element 201, second light-emitting element 202, and third light-emitting element 203.

Specifically, each of the first, second and third light-emitting elements 201, 202, 203 may include a semiconductor stack unit, and the semiconductor stack unit may include a first semiconductor layer, a second semiconductor layer, and an active layer disposed therebetween. The first semiconductor layer may be an n-type semiconductor layer, the second semiconductor layer may be a p-type semiconductor layer, and the active layer may be a multilayered quantum well layer which emits red light, green light, or blue light. The n-type semiconductor layer, the multilayered quantum well layer, and the p-type semiconductor layer are merely basic components of each of the first, second and third light-emitting elements 201, 202, 203. Based on these basic components, each of the first, second and third light-emitting elements 201, 202, 203 may further include other functional layers that optimize the performance thereof.

The first light-emitting element 201, the second light-emitting element 202, and the third light-emitting element 203 may respectively radiate light of different wavelength ranges. For instance, the first light-emitting element 201 may radiate blue light, the second light-emitting element 202 may radiate green light, and the third light-emitting element 203 may radiate red light. In some embodiments, the first, second and third light-emitting elements 201, 202, 203 respectively have the semiconductor stack layers of different types so that they emit light of different wavelength ranges. Selection of a material for each of the semiconductor stack layers relies upon a wavelength range of light emitted thereby. Examples of the material may include, but are not limited to, aluminum gallium arsenide, gallium arsenide phosphide, aluminum gallium indium phosphide, gallium nitride, indium gallium nitride, zinc selenide, and gallium phosphide. In still some embodiments, the first, second and third light-emitting elements 201, 202, 203 have the semiconductor stack layers of a same type, so as to radiate light of a same wavelength range. For example, all of the semiconductor stack layers of the first, second and third light-emitting elements 201, 202, 203 may emit blue light, but the blue light emitted from the second light-emitting element 202 may be eventually converted to green light due to the presence of a wavelength conversion layer on a light-emitting surface of the second light-emitting element 202, and the blue light emitted from the third light-emitting element 203 may be eventually converted to red light due to the presence of another wavelength conversion layer on a light-emitting surface of the third light-emitting element 203.

Each of the first, second and third light-emitting elements 201, 202, 203 may further include a first electrode and a second electrode. Each of the semiconductor stack layers has a mesa from which the first semiconductor layer is exposed. The first electrode is formed on the mesa and electrically connected to the first semiconductor layer. The second electrode is formed on the second semiconductor layer and electrically connected to the second semiconductor layer.

In certain embodiments, a thickness difference between any two of the first, second and third light-emitting elements 201, 202, 203 is less than or equal to 5 μm, so that the transfer yield of the light-emitting module 10 onto a transparent layer 100, which will be described hereinafter, can be effectively improved, thereby enhancing the light extraction efficiency of the light-emitting module 10.

Referring to FIGS. 1 and 2, in other embodiments, the light-emitting module 10 may further include the transparent layer 100. The light-emitting element 200 is disposed on the transparent layer 100. A surface of the transparent layer 100 distant from the light-emitting element 200 is a light-emitting surface of the light-emitting module 10. That is to say, light radiated from the light-emitting element 200 is emitted outside through the transparent layer 100. Additionally, the transparent layer 100 has a light transmittance of greater than 60% in the wavelength range of visible light.

Referring to FIG. 2, in still other embodiments, the transparent layer 100 includes a first transparent layer 1001 and a second transparent layer 1002. The second transparent layer 1002 is disposed between the first transparent layer 1001 and the light-emitting element 200.

The first transparent layer 1001 may be made of an inorganic light-transmitting material, such as glass, a transparent ceramic, or a sapphire. The light-emitting module 10 is required to have a certain thickness to facilitate use thereof. Therefore, in some embodiments, the first transparent layer 1001 has a thickness greater than 10 μm, for example, the thickness may range from 30 μm to 50 μm, from 50 μm to 100 μm, or from 100 μm to 300 μm.

Since the second transparent layer 1002 is disposed between the first transparent layer 1001 and the light-emitting element 200, the light-emitting element 200 can be bound to the first transparent layer through the second transparent layer 1002. The second transparent layer 1002 may entirely cover a surface of the first transparent layer 1001. In addition, the second transparent layer 1002 may not entirely cover the surface of the first transparent layer 1001, that is, the second transparent layer 1002 may be located below the light-emitting element 200 so that the light-emitting element 200 can be bound to the first transparent layer 1001 through the second transparent layer 1002.

The first, second and third light-emitting elements 201, 202, 203 may have different thicknesses. By disposing the second transparent layer 1002 between the first transparent layer 1001 and the light-emitting element 200 (i.e., any one of the first, second and third light-emitting elements 201, 202, 203), height differences between any two of the light-emitting surfaces 2001 of the first, second and third light-emitting elements 201, 202, 203 may be reduced, so that the light emitted from a side of the light-emitting element 200 can be absorbed by the filling layer 210, thereby improving a contrast of the light-emitting module 10. The second transparent layer 1002 may have a thickness ranging from 1 μm to 15 μm, or ranging from 3 μm to 10 μm. If the thickness of the second transparent layer 1002 is greater than 15 μm, the alignment accuracy of the light-emitting element 200 may be affected.

Due to a high cost of an inorganic light-transmitting material such as sapphire and complicated process for producing the same, in certain embodiments, the first transparent layer 1001 may be made of a relatively low cost thermosetting organic material, such as epoxy resin, silicone, or polyimide. The first transparent layer 1001 may also be made of a light-transmissible organic material, such as epoxy resin, silicone, or polyimide with nanoparticles dispersed therein. The nanoparticles may be nanoparticles of zirconium dioxide, silicon oxide, aluminum oxide, or boron nitride, which may improve the strength of the first transparent layer 1001. In addition, the contrast of the light-emitting module 10 can be adjusted by adjusting the content of the nanoparticles of zirconium dioxide, silicon oxide, aluminum oxide, or boron nitride present in the first transparent layer 1001. In an embodiment, the first transparent layer 1001 is made of a thermosetting organic material, and the second transparent layer 1002 is omitted.

Referring to FIG. 2, in another embodiment, the filling layer 210 is filled in the space among the light-emitting elements 200 or filled around the side walls of the light-emitting elements 200 so as to avoid color mixing or light interference arising from two adjacent ones of the light-emitting elements 200, thus improving the contrast of the light-emitting module 10. The filling layer 210 may be a light-absorbing black layer.

Each of the light-emitting elements 200 may have a thickness ranging from 2 μm to 15 μm, and two adjacent ones of the light-emitting elements 200 have a distance of less than 50 μm. Therefore, in some embodiments, a material with a good fluidity before solidification is used for forming the filling layer 210. A black filler component having a particle size greater than one-tenth of the thickness of each of the light-emitting elements 200 is filled in the filling layer 210, so as to avoid the problem that the filling layer 210 has a poor covering effect on the light-emitting elements 200 due to an excessive particle size of the black filler component, which may further affect the contrast of the light-emitting module 10. The filling layer 210 may be made of a transparent or translucent material, such as silicone, epoxy resin, polyimide, low-temperature glass, polysiloxane, or polysilazane, which is dispersed with the black filler component having the particle size not greater than 1 μm. Examples of the black filler component in the filling layer 210 may include, but are not limited to, carbon black, titanium nitride, iron oxide, ferrous-ferric oxide, and an iron powder. The particle size of the black filler component may range from 10 nm to 100 nm, from 100 nm to 200 nm, from 200 nm to 300 nm, or from 300 nm to 500 nm. The black filler component may be replaced with a black dye.

The filling layer 210 covers at least 50% of a side wall of each of the light-emitting elements 200 which is closer to the light-emitting surface 2001. In some embodiments, the filling layer 210 entirely covers the side wall of the each of the light-emitting elements 200, so as to avoid color mixing and light interference arising from two adjacent ones of the light-emitting elements 200, thereby improving the contrast of the light-emitting module 10. In other embodiments, the filling layer 210 has a thickness greater than the thickness of each of the light-emitting elements 200, so as to prevent light interference caused by light leakage from a bottom of the light-emitting elements 200. The thickness of the filling layer 210 may be less than 15 μm.

Referring to FIG. 2, in certain embodiments, the wiring layer 300 is formed above the light-emitting elements 200 and is electrically connected to the light-emitting elements 200. The wiring layer 300 may include several wirings. Referring to FIG. 4, in certain embodiments, the wiring layer 300 includes a first wiring 301, a second wiring 302, a third wiring 303, and a fourth wiring 304. The first wiring 301 serves as a common wiring, and the first electrodes of the first light-emitting element 201, the second light-emitting element 202, and the third light-emitting element 203 are commonly connected to the first wiring 301. In addition, the second electrode of the first light-emitting element 201 is connected to the second wiring 302, the second electrode of the second light-emitting element 202 is connected to the third wiring 303, and the second electrode of the third light-emitting element 203 is connected to the fourth wiring 304. The first wiring 301, the second wiring 302, the third wiring 303, and the forth wiring 304 of the wiring layer 300 may all be formed above the filling layer 210.

In other embodiments, the first wiring 301 serves as a common wiring, and the second electrodes of the first light-emitting element 201, the second light-emitting element 202, and the third light-emitting element 203 are commonly connected to the first wiring 301. In addition, the first electrode of the first light-emitting element 201 is connected to the second wiring 302, the first electrode of the second light-emitting element 202 is connected to the third wiring 303, and the first electrode of the third light-emitting element 203 is connected to the fourth wiring 304. The first wiring 301, the second wiring 302, the third wiring 303, and the forth wiring 304 of the wiring layer 300 may all be formed above the filling layer 210.

The wiring layer 300 has an upper surface and a lower surface opposite to each other. The lower surface of the wiring layer 300 is in contact with the filling layer 210 and the light-emitting elements 200, and the package layer 600 is formed above the upper surface of the wiring layer 300.

The wiring layer 300 may be a single-layer structure or multilayered structure made of at least one material, e.g., titanium, copper, chromium, nickel, gold, platinum, aluminum, titanium nitride, tantalum nitride, and tantalum. In this embodiment, the wiring layer 300 includes a first layer 310 and a second layer 320. The first layer 310 is in direct contact with the light-emitting elements 200, and the second layer 320 is formed on the first layer 310. The first layer 310 is used to attach the second layer 320 to the light-emitting elements 200 and the filling layer 210, and the second layer 320 mainly plays a conductive role. The first layer 310 may be made of a material, which includes, but are not limited to titanium, nickel, titanium nitride, tantalum nitride, tantalum, and combinations thereof. The second layer 320 may be made of a material, which includes, but are not limited to, copper, aluminum, gold, and combinations thereof. The wiring layer 300 may be made by sputtering, evaporation, and so forth.

The wiring layer 300 may have a thickness ranging from 50 nm to 1000 nm. The first layer 310 may have a thickness ranging from 10 nm to 200 nm, and the second layer 320 may have a thickness ranging from 200 nm to 800 nm. The thickness of the first layer 310 may be less than the thickness of the second layer 320.

Referring to FIGS. 2 and 4, in certain embodiments, the conductive pads 500 are formed on a side of the wiring layer 300 distant from the light-emitting elements 200, and are electrically connected to the light-emitting elements 200 via the wiring layer 300.

The conductive pads 500 may include a first pad 501, a second pad 502, a third pad 503, and a fourth pad 504. The first pad 501 may serve as a common pad, and the first electrodes of the first light-emitting element 201, the second light-emitting element 202, and the third light-emitting element 203 are commonly connected to the first pad 501 via the first wiring 301. The second electrode of the first light-emitting element 201 is connected to the second pad 502 via the second wiring 302, the second electrode of the second light-emitting element 202 is connected to the third pad 503 via the third wiring 303, and the second electrode of the third light-emitting element 203 is connected to the fourth pad 504 via the fourth wiring 304.

In some embodiments, the first pad 501 serves as a common pad, and the second electrodes of the first light-emitting element 201, the second light-emitting element 202, and the third light-emitting element 203 are commonly connected to the first pad 501 via the first wiring 301. The first electrode of the first light-emitting element 201 is connected to the second pad 502 via the second wiring 302, the first electrode of the second light-emitting element 202 is connected to the third pad 503 via the third wiring 303, and the first electrode of the third light-emitting element 203 is connected to the fourth pad 504 via the fourth wiring 304.

Each of the conductive pads 500 may include a conductive layer 510. The conductive layer 510 may be a single-layer structure or a multilayered structure made of at least one material, e.g., titanium, copper, gold, and platinum. In addition, the conductive layer 510 may have a thickness ranging from 10 μm to 50 μm. For instance, the thickness may be 20 μm, 30 μm, or 40 μm.

In some embodiments, each of the conductive pads 500 includes not only the conductive layer 510 but also a protective layer 530, both of which are sequentially formed on the wiring layer 300. If the protective layer 530 completely covers an upper surface of the conductive layer 510 before the light-emitting module 10 is installed onto a display device, the conductive layer 510 may be effectively protected from being oxidized upon installation of the light-emitting module 10, thereby enhancing the stability of the light-emitting module 10. When the light-emitting module 10 is installed onto the display device, the protective layer 530 may be damaged or removed. The protective layer 530 will not affect the bonding and conductivity of the conductive pads 500. Additionally, the protective layer 530 may have a thickness ranging from 25 nm to 50 nm.

The protective layer 530 may be made of a metal material such as gold or platinum. During the installation of the light-emitting module 10 onto the display device, the conductive pads 500 are welded to a circuit board by utilizing a welding material at a predetermined temperature. During the welding process, the welding material flows and deforms, which may destroy the integrity of the protective layer 530 made of gold, platinum or another metal material.

In other embodiments, the protective layer 530 is made of an organic material such as an organic solderability preservative (OSP). When the light-emitting module 10 is installed onto the display device, in which the conductive pads 500 are welded to the circuit board by utilizing the welding material at the predetermined temperature, the organic material (e.g., OSP) is dissolved at such predetermined temperature, and hence removed.

In still some embodiments, each of the conductive pads 500 includes an adhesive layer 520 disposed between the conductive layer 510 and the protective layer 530. The adhesive layer 520 may be a single-layer structure or a multilayered structure made of at least one material, e.g., chromium, titanium, nickel, tantalum nitride, tantalum, and so forth. The adhesive layer 520 may have a thickness ranging from 3 μm to 5 μm.

In some embodiments, each of the conductive pads 500 has a thickness greater than or equal to 5 μm. The conductive pads 500 may be made by electroplating.

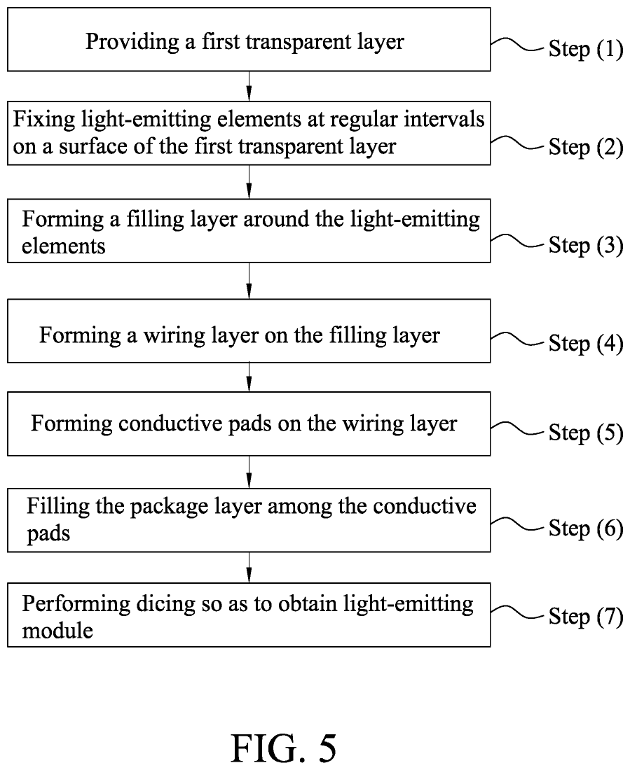

A method for manufacturing the aforesaid light-emitting module 10 is also provided. Referring to FIG. 5, the method may include the following steps:
(1) providing the first transparent layer 1001;
(2) fixing the light-emitting elements 200 at regular intervals on a surface of the first transparent layer 1001;
(3) forming the filling layer 210 around the light-emitting elements 200;
(4) forming the wiring layer 300 on the filling layer 210;
(5) forming the conductive pads 500 on the wiring layer 300, each of the conductive pads 500 having the thickness greater than or equal to 5 μm and being in direct contact with the wiring layer 300;
(6) filling the package layer 600 among the conductive pads 500; and
(7) performing dicing so as to obtain the light-emitting module 10.

A detailed description with reference to the drawings is provided hereinafter.

In step (1), the first transparent layer 1001 may have a configuration as described above. The first transparent layer 1001 may include a first surface and a second surface, and the first surface is the light-emitting surface.

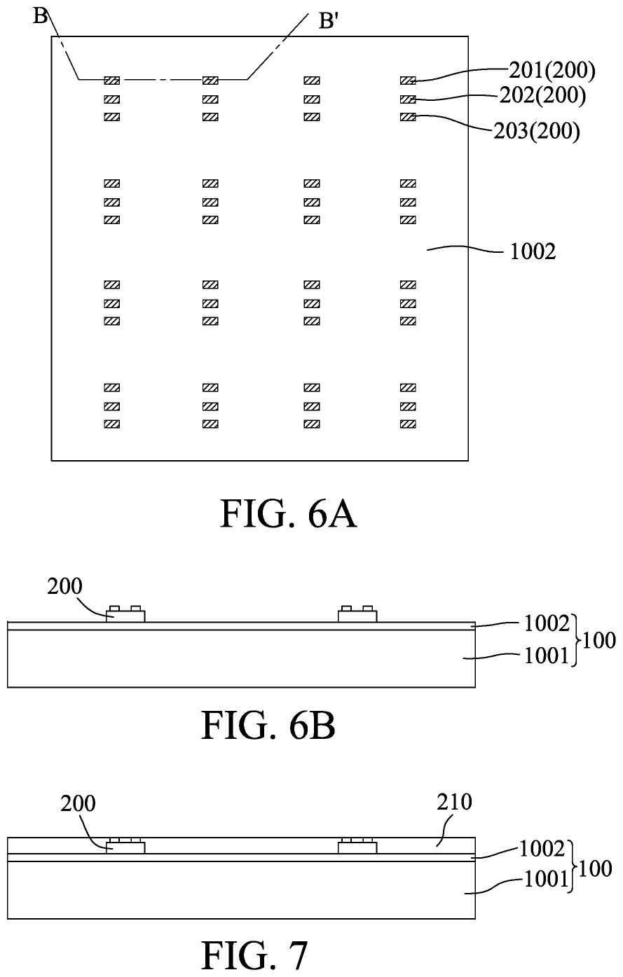

Referring to FIGS. 6A and 6B, in step (b), the light-emitting elements 200 arranged in a series of arrays are fixed on the second surface of the first transparent layer 1001. Each of the arrays includes a series of light-emitting units, and each of the light-emitting units corresponds to a pixel point, and includes at least three of the light-emitting elements 200 (e.g., the first, second and third light-emitting elements 201, 202, 203) that radiate light with different wavelength ranges. In certain embodiments, the first transparent layer 1001 is a sapphire substrate, and the light-emitting elements 200 are bound to the first transparent layer 1001 through the second transparent layer 1002. The second transparent layer 1002 may have a configuration as described above. The second transparent layer 1002 covers the second surface of the first transparent layer 1001.

Referring to FIG. 7, in step (3), the filling layer 210 is formed around the light-emitting elements 200. That is to say, the filling layer 210 is filled among the light-emitting elements 200 or filled around the side walls of the light-emitting elements 200.

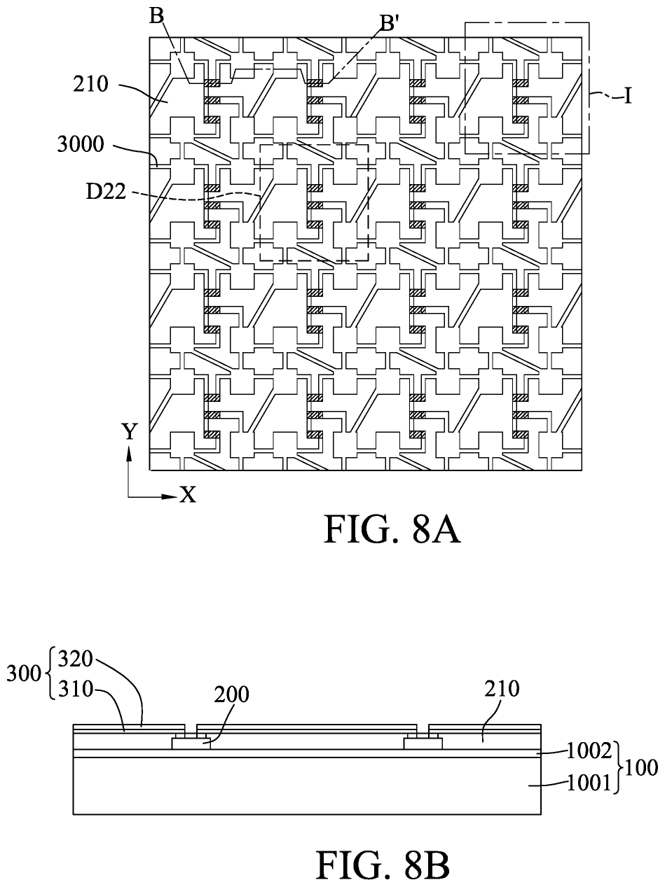

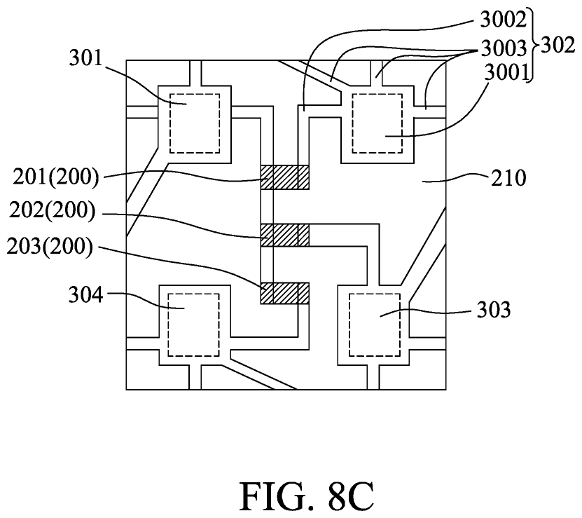

Referring to FIGS. 8A and 8B, a wiring unit 3000 is formed on the filling layer 210. The wiring unit 3000 may include a plurality of the wiring layers 300 that are unitized. The wiring layers 300 thus unitized are arranged in columns in a first direction (X) as well as in rows in a second direction (Y). The first direction (X) and the second direction (Y) are perpendicular to each other. Referring to FIG. 8C, each of the wiring layers 300 that are unitized includes the first wiring 301, the second wiring 302, the third wiring 303, and the fourth wiring 304. The first light-emitting element 201 is electrically connected to the first wiring 301 and the second wiring 302, the second light-emitting element 202 is electrically connected to the first wiring 301 and the third wiring 303, and the third light-emitting element 203 is electrically connected to the first wiring 301 and the fourth wiring 304. Each of the first, second, third, and fourth wirings 301, 302, 303, 304 has a first region 3001, a second region 3002, and a third region 3003. The first region 3001 is a region that overlaps with a corresponding one of the conductive pads 500 from a top perspective view, the second region 3002 is connected to the light-emitting elements 200 and the first region 3001, and the third region 3003 extends from the first region 3001 to an edge of the light-emitting module 10.

Referring to FIG. 8A, the wiring layer 300(3000) that is unitized and located in the second column and the second row is taken as an example for explaining the connection relationship among the wiring layers 300 of different units. It should be noted here that the wiring layer 300 that is unitized and located in the first row and the first column is referred to as “D11”, the wiring layer 300 that is unitized and located in the second row and the third column is referred to as “D23”, the wiring layer 300 that is unitized and located in the third row and the fifth column is referred to as “D35”, and so on. The first wiring 301 of D22 is connected to the fourth wiring 304 of D12, the second wiring 302 of D21, and the third wiring 303 of D21. The second wiring 302 of D22 is connected to the third wiring 303 of D12, the fourth wiring 304 of D12, and the first wiring 301 of D23. The third wiring 303 of D22 is connected to the second wiring 302 of D32, the first wiring 301 of D23, and the fourth wiring 304 of D23. The fourth wiring 304 of D22 is connected to the third wiring 303 of D21, the first wiring 301 of D32, and the second wiring 302 of D32. The connection relationship of the remaining wiring layers 300 that are unitized is similar to that described in the foregoing, such that the wiring unit 3000 is in an interconnected state.

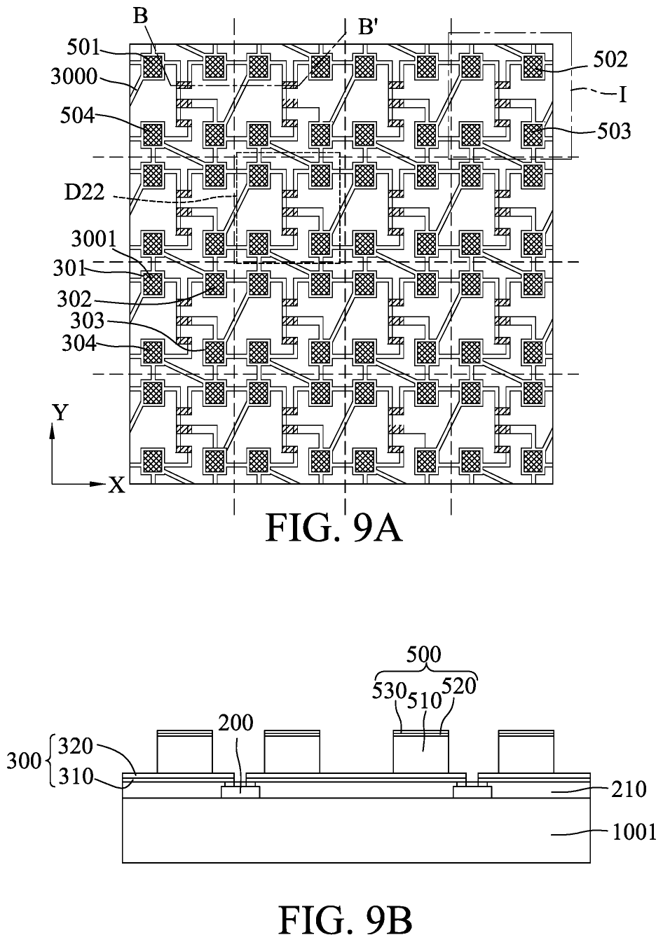

Referring to FIGS. 9A and 9B, in step (5), the conductive pads 500 are formed on the wiring layers 300. The conductive pads 500 are formed on the first regions 3001 of the wirings 301, 302, 303, 304 of the wiring layers 300 by electroplating. Each of the conductive pads 500 has the thickness greater than or equal to 5 μm, and is in direct contact with the corresponding one of the first regions 3001.

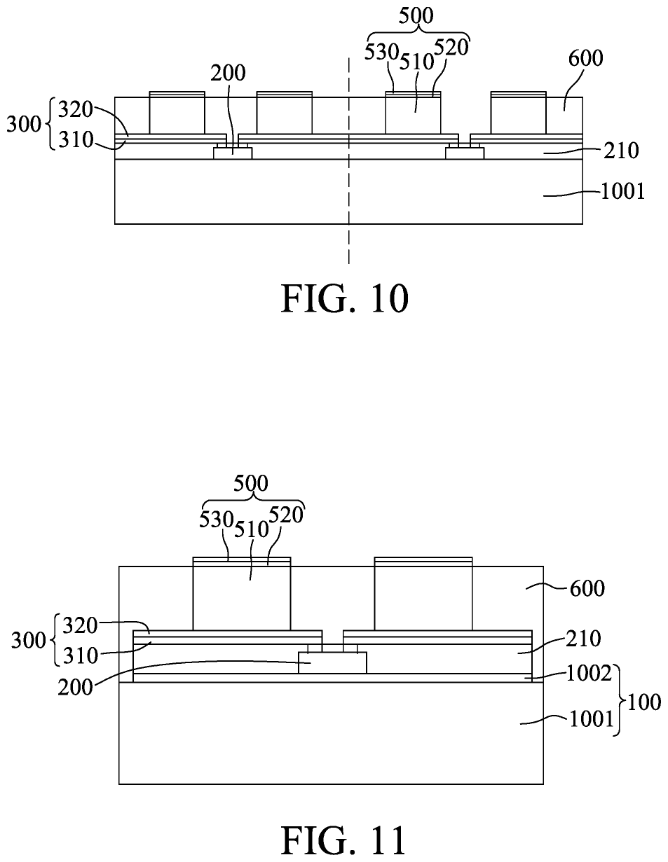

Referring to FIG. 10, in step (6), the package layer 600 is filled around the conductive pads 500. The package layer 600 may have a configuration as described above. The package layer 600 is formed with the guiding structure 900, such as the groove in this embodiment. In certain embodiments, the package layer 600 is initially filled around the conductive pads 500 so as to form a plane structure, and then a portion of the plane structure is cut off and removed, thereby forming the groove.

In some embodiments, a laser cutting method is used to cut off the portion of the plane structure (i.e., the package layer 600), so as to form the groove. The laser cutting method is relatively easy to perform, and is controllable in operation to obtain a desired shape of the groove. For example, the laser cutting method may be better to ensure that a side wall of the groove is perpendicular or nearly perpendicular to a surface of the package layer 600. However, the laser cutting method may cause the side wall of the groove to be relatively rough (not smooth), which affects the movement of the light-emitting module 10 on the track 230 during sorting to be performed subsequently. Therefore, a width of the groove may be increased to a proper degree such that the width of the groove is greater than that of the sorting structure 231.

In other embodiments, an etching method may be used to cut off the portion of the package layer 600, thereby forming the groove. For example, a photoresist layer with a pattern corresponding to the groove is formed above the package layer 600, and then the package layer 600 is etched through the pattern, thereby forming the groove. The etching method may facilitate smoothening of the side wall of the groove. An end of the side wall of the groove made by the etching method may usually be in a shape of a chamfer so as to form the chamfered portion 900A. That is to say, the end of the side wall of the groove may form a certain angle with respect to other portion of the side wall. The characteristic of the end of the side wall of the groove (i.e., the chamfered portion 900A of the groove) may facilitate the engagement of the groove with the sorting structure 231 of the track 230.

After formation of the groove, the chamfered portion 900A having the two chamfered surface 9001 is formed at the one end of the straight portion 900B.

In step (7), the dicing is performed so as to obtain the light-emitting module 10.

Referring to FIG. 10, the dicing may be performed along the dotted line, thereby obtaining the light-emitting module 10.

In the method of this embodiment, the wiring layers 300 are designed so that before dicing, each of the wiring layers 300 unitized is in an interconnection state and the conductive pads 500 may be formed at corresponding positions (i.e., the first regions 3001) in each of the wiring layers 300 that are unitized by electroplating or by other methods, thus simplifying the manufacturing process. Furthermore, during the process of preparing the conductive pads 500 by electroplating, surfaces of the wiring layers 300 may be wet-etched to remove an oxide layer thereon, so that the wiring layers 300 are in direct contact with the conductive pads 500, thus avoiding the situation of poor electrical bonding caused by oxidation of the wiring layers 300.

Referring to FIG. 11, in other embodiments, the package layer 600 covers sidewalls of the wiring layers 300, which can prevent poor electrical properties caused by oxidization of the wiring layers 300 that are exposed at the edge of the light-emitting module 10.

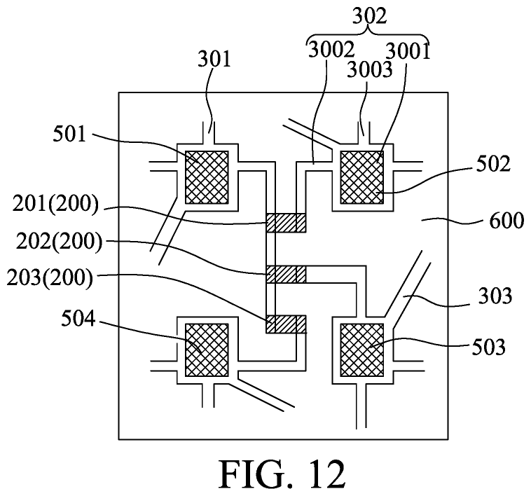

Referring to FIG. 12, in still other embodiments, a portion of the wiring layers 300 extending toward the edge of the light-emitting module 10 are etched, so as to avoid poor electrical properties caused by oxidation of the wiring layers 300 that are exposed at the edge of the light-emitting module 10.

### Second Embodiment

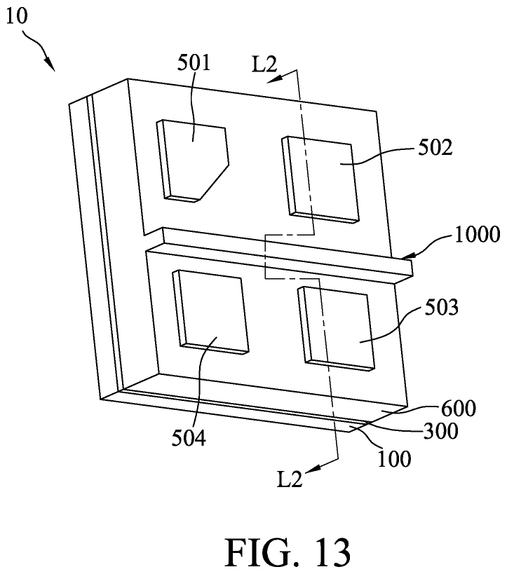

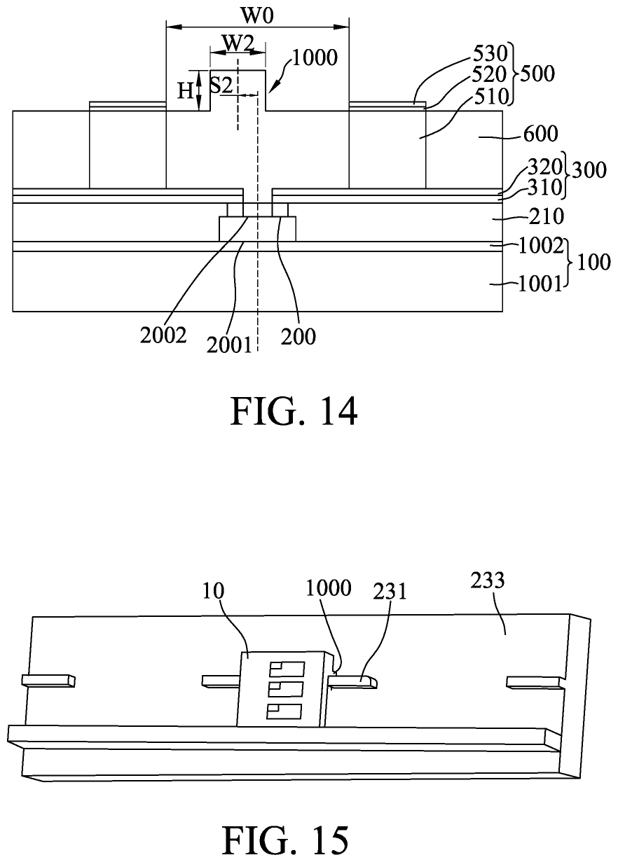

Referring to FIGS. 13 and 14, a second embodiment of the light-emitting module 10 according to this disclosure generally has a structure similar to that of the first embodiment, except for the guiding structure. In this embodiment, the light-emitting module 10 includes a plurality of the light-emitting elements 200 that are spacedly arranged, a plurality of the conductive pads 500, and the package layer 600. Each of the light-emitting elements 200 has the light-emitting surface 2001. The conductive pads 500 and the package layer 600 are formed at a side opposite to the light-emitting surfaces 2001 of the light-emitting elements 200. The package layer 600 is disposed around the conductive pads 500, so as to electrically isolate two adjacent ones of the conductive pads 500. In certain embodiments, a surface of the package layer 600 away from a wiring layer 300 is flush with surfaces of the conductive layers 510 of the conductive pads 500 away from the wiring layer 300. The package layer 600 is formed with a guiding structure 1000 which is formed between two adjacent ones of the conductive pads 500 and which extends in a direction orthogonal to the thickness direction of the package layer 600 so as to extend across the package layer 600.

The differences between the light-emitting module 10 of this embodiment and the light-emitting module 10 of the first embodiment are described as follows. In this embodiment, the guiding structure 1000 is a protrusion. Referring to FIGS. 13 and 14, the protrusion is formed between the two adjacent ones of the conductive pads 500, and is disposed relatively offset to the center line of the light-emitting module 10. That is to say, a center line of the protrusion is separated from the center line of the light-emitting module 10 by a distance (S2). The distance (S2) may range from 10 μm to 60 μm. In certain embodiments, the distance (S2) ranges from 20 μm to 40 μm.

Referring to FIG. 15, the setting of the distance (S2) enables the light-emitting module 10 to fit with the sorting structure 231 of the track 230 during sorting, and the light-emitting module 10 and the sorting structure 231 can only match with each other in a certain direction, thereby enabling directional sorting of the light-emitting module 10, reducing the use of the image sensors or camera devices, and improving sorting efficiency.

In order to ensure the integrity of the package layer 600 without adversely affecting the functionality thereof, the protrusion (i.e., the guiding structure 1000) may have a width (W2) ranging from 10% to 65% of a distance (W0) between two adjacent ones of the conductive pads 500. In addition, the protrusion may have a height (H) ranging from one-twelfth to one-quarter of a thickness of the light-emitting module 10. In certain embodiments, the height (H) of the protrusion is greater than 10 μm and is not greater than 30 μm. In some embodiments, the width (W2) of the protrusion is less than 50 μm, and the height (H) thereof is less than 30 μm. Referring to FIG. 15, the protrusion can match with sorting structure 231 of the track 230 and is located above the sorting structure 231, so that the protrusion and the sorting structure 231 form an appropriate fit. As shown in FIG. 15, the width (W2) and the height (H) of the protrusion are set in such a way that the protrusion can fit with the sorting structure 231 of the track 230, that the light-emitting module 10 does not fall off, and that the integrity and functionality of the package layer 600 are not affected. Since the height (H) of the protrusion is not greater than 30 μm, the overall flatness of the package layer 600 will not be affected, and welding or die-bonding process of the light-emitting module 10 to be performed subsequently will not be affected.

### Third Embodiment

A third embodiment of the light-emitting module 10 according to this disclosure is further provided. The light-emitting module 10 has a three-dimensional structure which is formed with a guiding structure 900. In addition, the guiding structure extends in a direction orthogonal to a thickness direction of the three-dimensional structure so as to extend across the three-dimensional structure. The guiding structure 900 may be formed either as a groove or a protrusion. For convenience, the guiding structure 900 formed as the groove is taken as an example herein for further description of the guiding structure 900. The light-emitting module 10 of this embodiment has a structure similar to that of the first embodiment. The similarities between the light-emitting module 10 of this embodiment with that of Embodiment 1 will not be further described, and the differences therebetween are as follows.

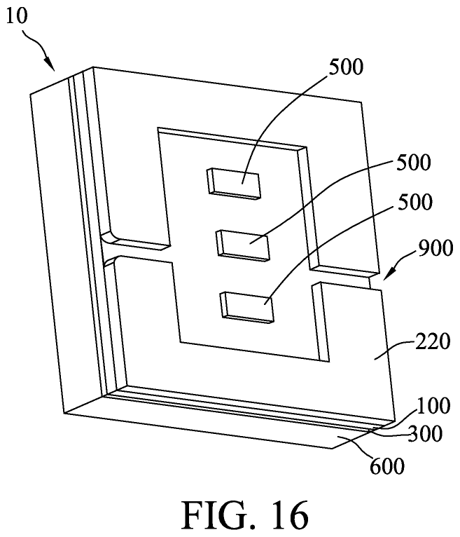

Referring to FIG. 16, in some embodiments, the light-emitting module 10 includes a plurality of the light-emitting elements (not shown), a plurality of the conductive pads 500, and the package layer 600. The light-emitting elements are spacedly arranged and have different light-emitting wavelength ranges. In certain embodiments, each of the light-emitting elements has a light-emitting surface and a back surface opposite to the light-emitting surface. In addition, the light-emitting module 10 further includes the transparent layer 100 disposed above the light-emitting surfaces 2001 of the light-emitting elements 200, and the light-emitting elements 200 are disposed on the transparent layer 100. The light-emitting module 10 still further includes a light-shielding layer 220 formed on the transparent layer 100 to surround an area of the transparent layer 100 in which the light-emitting elements 200 are located. The light-shielding layer 220 may be made of a material containing a light-absorbing component. The material may be the same as or different from the material of the filling layer 210 or the package layer 600 of the light-emitting module 10 of the first embodiment. The groove is formed in the light-shielding layer 220 and extends in a direction orthogonal to a thickness direction of the light-emitting shielding layer 200 so as to extend across the light-shielding layer 200. In addition, the groove may have the same structural features as the groove of the light-emitting module 10 of the first embodiment, and thus relevant details of the groove may be obtained by referring to the description of Embodiment 1.

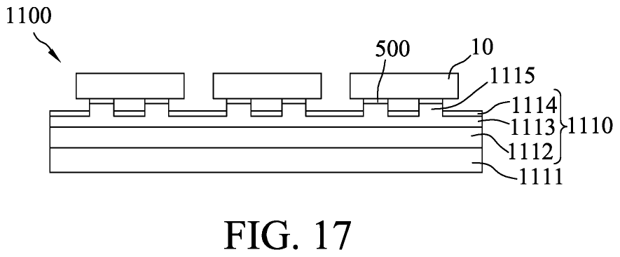

Referring to FIG. 17, an embodiment of a display device 1100 according to this disclosure includes a panel 1110 and a plurality of light-emitting modules 10 disposed on the panel 1110. The light-emitting modules 10 are the same as those mentioned in the aforesaid embodiments.

Referring to FIG. 17, the panel 1110 includes a substrate 1111, a device layer 1112 formed on the substrate 1111, a circuit layer 1113 formed on the device layer 1112, and a protective layer 1114 formed on the circuit layer 1113. In addition, the device layer 1112 is electrically connected to the circuit layer 1113. The circuit layer 1113 includes electrodes 1115 extending through the protective layer 1114. The light-emitting modules 10 are welded to the electrodes 1115 through the conductive pads 500, thereby enabling electrical connection between the light-emitting modules 10 and the circuit layer 1113, and allowing the light-emitting modules 10 to be electrically connected to the device layer 1112, which controls the turning on and off of the light-emitting modules 10. Briefly, each of the light-emitting modules 10 is electrically connected to the device layer 1112 via the circuit layer 1113.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting module, comprising:
a plurality of light-emitting elements that are spacedly arranged, each of said light-emitting elements having a light-emitting surface and a back surface opposite to said light-emitting surface;
a plurality of conductive pads disposed above said back surfaces of said light-emitting elements; and
a package layer disposed around said conductive pads, said package layer having a guiding structure which is formed between two adjacent ones of said conductive pads and which extends in a direction orthogonal to a thickness direction of said package layer so as to extend across said package layer.

2. The light-emitting module as claimed in claim 1, wherein a center line of said guiding structure is separated from a center line of said light-emitting module by a distance ranging from 10 μm to 60 μm.

3. The light-emitting module as claimed in claim 1, wherein said guiding structure has a width ranging from 10% to 65% of a distance between said two adjacent ones of said conductive pads.

4. The light-emitting module as claimed in claim 1, wherein said guiding structure is a groove having a depth which ranges from one-twentieth to one-third of a thickness of said light-emitting module and which is less than a thickness of said package layer.

5. The light-emitting module as claimed in claim 4, wherein the depth of said groove ranges from 10 μm to 40 μm.

6. The light-emitting module as claimed in claim 4, wherein said groove includes a straight portion having two inner surfaces which face each other, and a chamfered portion which is formed at one end of said straight portion and which has two chamfered surfaces respectively extending from said inner surfaces of said straight portion, a chamfer angle of each of said chamfered surfaces with respect to a corresponding one of said inner surfaces ranging from 15 degrees to 60 degrees.

7. The light-emitting module as claimed in claim 1, wherein said guiding structure is a protrusion having a height which is greater than 10 μm and is not greater than 30 μm.

8. The light-emitting module as claimed in claim 1, wherein the direction along which said guiding structure extends is a length direction of said light-emitting module, said guiding structure having two opposite ends having the same width.

9. The light-emitting module as claimed in claim 1, wherein a center line of said guiding structure is aligned with a center line of said light-emitting module.

10. The light-emitting module as claimed in claim 1, wherein said package layer has a thickness greater than 20 μm.

11. The light-emitting module as claimed in claim 1, wherein each of said conductive pads has an exposed surface which is exposed from said package layer, said light-emitting module has a top surface including a surface of said package layer and said exposed surface of each of said conductive pads, and a total surface area of said exposed surfaces of said conductive pads ranges from 20% to 70% of a surface area of said top surface of said light-emitting module.

12. A light-emitting module, comprising a plurality of light-emitting elements that are spacedly arranged, said light-emitting module having a three-dimensional structure which is formed with a guiding structure, said guiding structure extending in a direction orthogonal to a thickness direction of said three-dimensional structure so as to extend across said three-dimensional structure.

13. The light-emitting module as claimed in claim 12, wherein:
each of said light-emitting elements has a light-emitting surface and a back surface opposite to said light-emitting surface; and
said light-emitting module further includes:
a transparent layer disposed above said light-emitting surfaces of said light-emitting elements, said light-emitting elements being disposed on said transparent layer; and
a light-shielding layer formed on said transparent layer to surround an area of said transparent layer in which said light-emitting elements are located, said guiding structure being formed in said light-shielding layer and extending in a direction orthogonal to a thickness direction of said light-shielding layer so as to extend across said light-shielding layer.

14. The light-emitting module as claimed in claim 12, wherein:
each of said light-emitting elements has a light-emitting surface and a back surface opposite to said light-emitting surface;
said light-emitting module further includes:
a substrate having a first surface on which said light-emitting elements are disposed in a manner that said back surface of each of said light-emitting elements faces said first surface of said substrate, and a second surface opposite to said first surface, and
a plurality of conductive pads formed on said second surface of said substrate and electrically connected to said light-emitting elements; and
said guiding structure is formed on said second surface of said substrate, is disposed between two adjacent ones of said conductive pads, and extends in a direction orthogonal to a thickness direction of said substrate so as to extend across said substrate.

15. A method for sorting light-emitting modules, comprising the steps of:
(a) feeding a plurality of light-emitting modules into a track of a sorting machine, each of the light-emitting modules having a guiding structure, the track of the sorting machine having a sorting structure; and
(b) moving the light-emitting modules along the track of the sorting machine, such that those of the light-emitting modules that have the guiding structures engaging with the sorting structure pass through the track of the sorting machine while those of the light-emitting modules that have the guiding structures not engaging with the sorting structure are blocked and are not allowed to pass through the track of the sorting machine, thereby sorting the light-emitting modules.

16. The method for sorting light-emitting modules as claimed in claim 15, wherein the track of the sorting machine further has a tipping structure which is configured to be capable of tipping the light-emitting modules to rotate, and wherein, in step (b), those of the light-emitting modules that are blocked by the sorting structure are each rotated by the tipping structure such that the guiding structures of the light-emitting modules become engaged with the sorting structure.

17. A display device, comprising:
a panel including a circuit layer and a device layer which is electrically connected to said circuit layer; and
a plurality of light-emitting modules disposed on said panel, each of said light-emitting modules being electrically connected to said device layer via said circuit layer,
wherein each of said light-emitting modules is a light-emitting module as claimed in claim 1.

18. A display device, comprising:
a panel including a circuit layer and a device layer which is electrically connected to said circuit layer; and
a plurality of light-emitting modules disposed on said panel, each of said light-emitting modules being electrically connected to said device layer via said circuit layer,
wherein each of said light-emitting modules is a light-emitting module as claimed in claim 12.
